(19) United States
(12) Patent Application Publication
(10) Pub. No.: US 2026/0075862 A1
(43) Pub. Date: Mar. 12, 2026

(54) METHOD FOR MAKING TRENCH MOSFET (TFET) DEVICES INCLUDING IN-SITU DOPED SUPERLATTICE LAYER

(71) Applicant: ATOMERA INCORPORATED, LOS GATOS, CA (US)

(72) Inventors: HIDEKI TAKEUCHI, SAN JOSE, CA (US); SHUYI LI, LOS GATOS, CA (US)

(21) Appl. No.: 19/320,363

(22) Filed: Sep. 5, 2025

Related U.S. Application Data
(60) Provisional application No. 63/691,669, filed on Sep. 6, 2024.
(60) Provisional application No. 63/702,808, filed on Oct. 3, 2024.
(60) Provisional application No. 63/875,599, filed on Sep. 4, 2025.

(51) Int. Cl. H10D 30/01; H10D 30/66; H10D 62/10; H10D 62/815; H10D 64/00

(52) U.S. Cl. CPC H10D 30/0297; H10D 30/668; H10D 62/111; H10D 62/8171; H10D 64/117

(57) ABSTRACT

A method for making a trench field effect transistor (TFET) may include forming a trench in a semiconductor layer, and forming a superlattice layer in the semiconductor layer extending along bottom and sidewall portions of the trench, the superlattice layer comprising a plurality of stacked groups of layers. Each group of layers may include a plurality of stacked base semiconductor monolayers defining a base semiconductor portion and at least one non-semiconductor monolayer, with each at least one non-semiconductor monolayer of each group of layers being constrained within a crystal lattice of adjacent base semiconductor portions. The method may further include forming source and drain regions defining, along with the superlattice layer, a channel region extending between the source and drain regions, and forming a gate within the trench comprising a gate insulator lining the trench and a gate electrode within the gate insulator.

### 1RELATED APPLICATIONS

This application claims the benefit of U.S. App. no. 63/702,808 filed Oct. 3, 2024 and U.S. App. No. 63/691,669 filed Sep. 6, 2024, and U.S. App. No. 63/875,599 filed Sep. 4, 2025 which are all hereby incorporated herein in their entireties by reference.

### TECHNICAL FIELD

The present disclosure generally relates to semiconductor devices, and, more particularly, to trench field effect transistor (TFET) devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (August 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a trench field effect transistor (TFET) may include forming a trench in a semiconductor layer, and forming a superlattice layer in the semiconductor layer extending along bottom and sidewall portions of the trench, the superlattice layer comprising a plurality of stacked groups of layers. Each group of layers may include a plurality of stacked base semiconductor monolayers defining a base semiconductor portion and at least one non-semiconductor monolayer, with each at least one non-semiconductor monolayer of each group of layers being constrained within a crystal lattice of adjacent base semiconductor portions. The method may further include forming source and drain regions defining, along with the superlattice layer, a channel region extending between the source and drain regions, and forming a gate within the trench comprising a gate insulator lining the trench and a gate electrode within the gate insulator.

The source and drain regions may have a first conductivity type, and the gate electrode may have a second conductivity type different than the first conductivity type.

The method may further include in-situ doping at least one base semiconductor portion of the superlattice layer between adjacent non-semiconductor monolayers. By way of example, the in-situ dopant may comprise phosphorous.

The method may also include forming a shield gate electrode within the gate insulator beneath the gate electrode. Furthermore, the semiconductor layer may have a first conductivity type adjacent a bottom of the trench defining a drift region, and a second conductivity type adjacent a top of the trench defining a body region. By way of example, the gate insulator may comprise an oxide, and the gate electrode may comprise a polysilicon gate electrode. Also by way of example, the base semiconductor monolayers may comprise silicon, and the at least one non-semiconductor monolayer may comprise oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross-sectional diagram of a trench FET (TFET) device including a superlattice trench liner in accordance with an example embodiment.

FIG. 5 is a graph of dopant concentration at different positions along line A-A′ of the TFET of FIG. 4.

FIG. 6 is a series of graphs illustrating electrical performance for the example implementation of the TFET of FIG. 4 vs. a control TFET without the superlattice trench liner.

FIG. 7 is a graph illustrating a series of plots of Rsp vs. BVdss for various conventional TFET devices and an example embodiment of the TFET of FIG. 4.

FIG. 8 is a schematic cross-sectional diagram illustrating another example embodiment of the TFET of FIG. 4 incorporating gate electrode counter doping to define a recessed channel region.

FIG. 9 is a flow diagram illustrating a method of fabricating a TFET in accordance with an example implementation.

### DETAILED DESCRIPTION

1Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

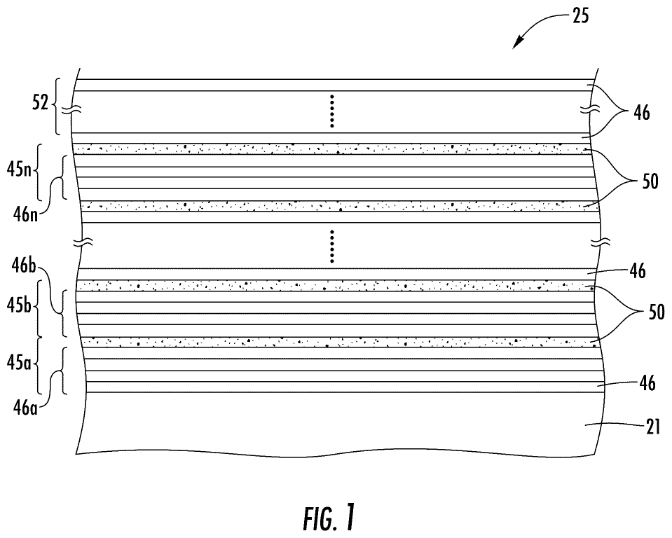

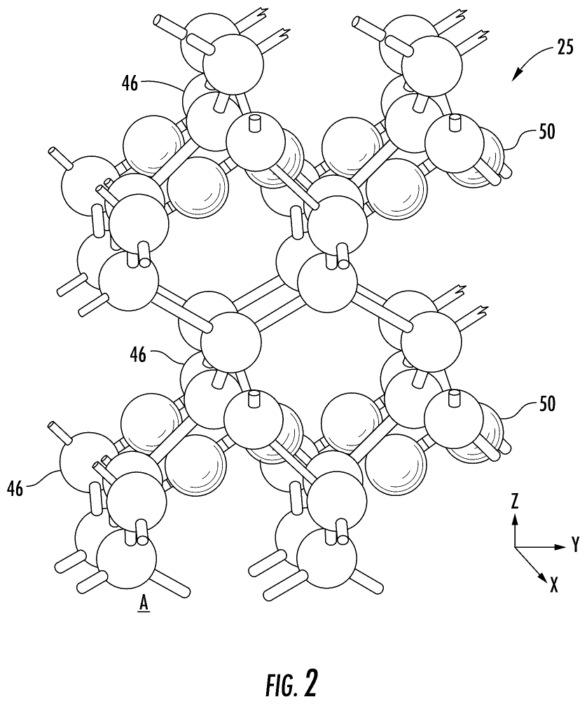

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46ₙ cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

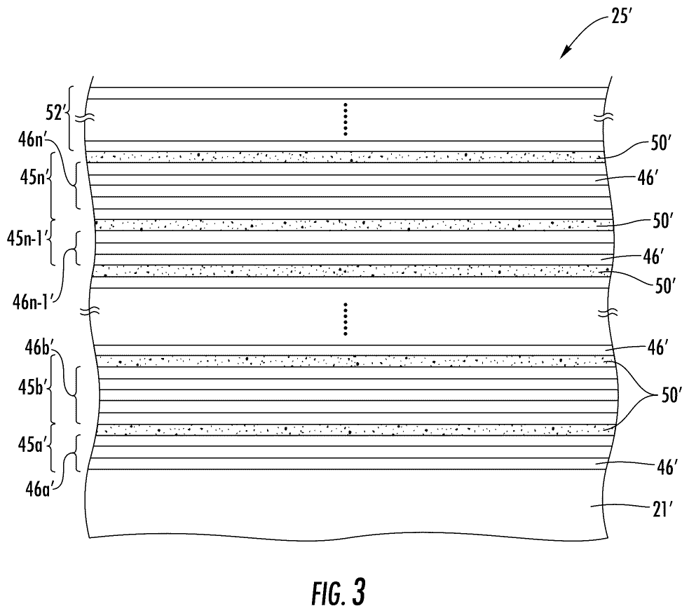

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

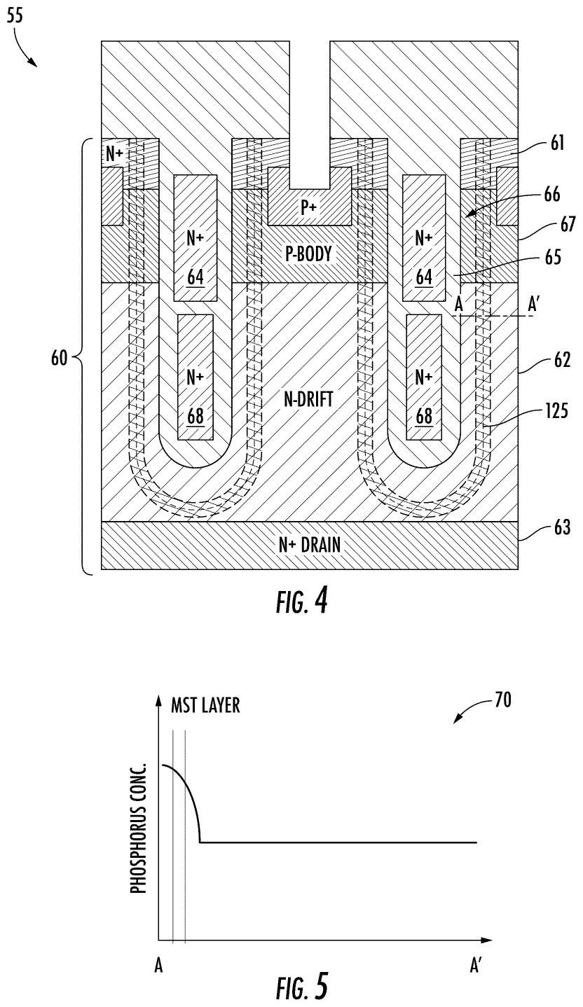

Turning now to FIG. 4, the above-described MST films may be incorporated within trench field effect transistor (TFET) devices such as the TFET 55. The TFET 55 illustratively includes a semiconductor layer or substrate 60 having a trench therein, source, drift, and drain regions 61, 62, 63 a polysilicon gate electrode 64 within the trench including a gate insulator 65 lining the trench, and a superlattice layer 125 in the semiconductor layer extending along bottom and sidewall portions of the trench and defining a channel region 66 extending between the source and drain regions. The superlattice 125 layer may be an MST film as described further above, and may include a cap layer 52 in which the channel region 66 is defined in some embodiments.

The semiconductor layer 60 has a first conductivity type (here N-type) adjacent to the bottom of the trench defining a drift region 62, and a second conductivity type (here P-type) opposite the first conductivity type adjacent a top of the trench defining a body region 67. A polysilicon gate electrode 64 has the first conductivity type. The TFET 55 may also illustratively include an optional shield gate electrode 68 within the gate insulator 65 beneath the gate electrode 63. By way of example, the gate insulator 64 may be SiO₂, and the gate electrode 65 and shield gate electrode 68 may be polysilicon, although other suitable materials may be used in different embodiments.

Furthermore, in some implementations one or more of the base semiconductor portions 46a-46n between non-semiconductor monolayers 50 of the superlattice 125 may be in-situ doped. For example, an MST film may be grown in the trench with in-situ phosphorus doped silicon between one or more pairs of adjacent oxygen inserted monolayers, although different materials and dopants may be used in different embodiments.

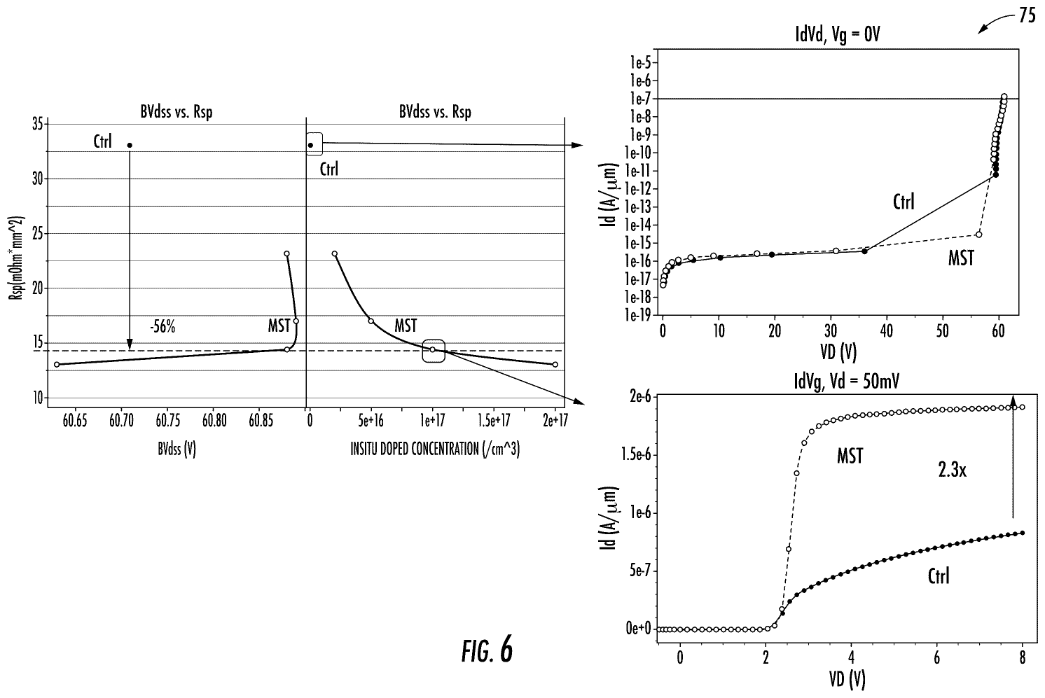

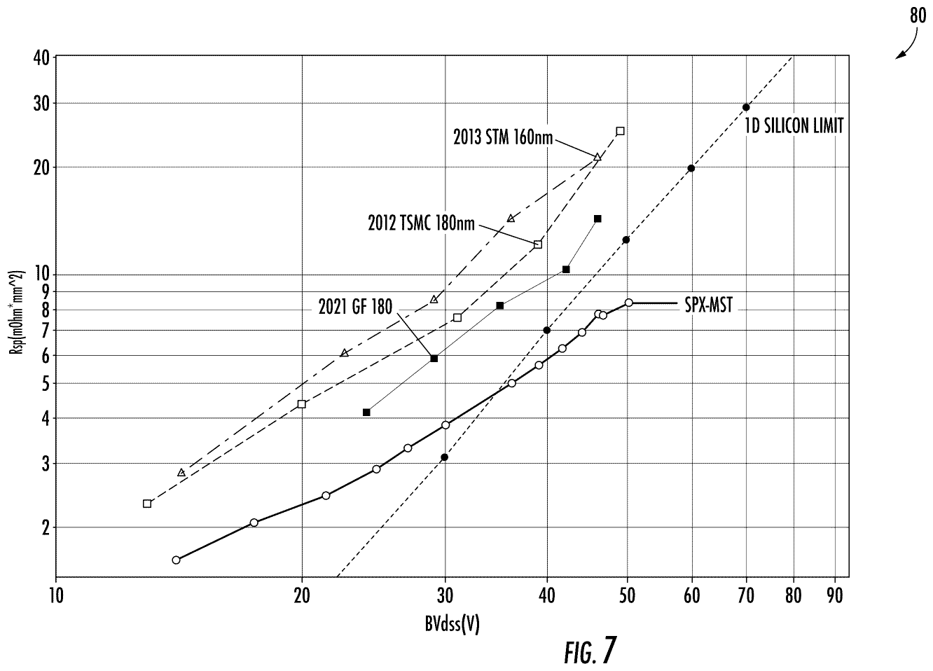

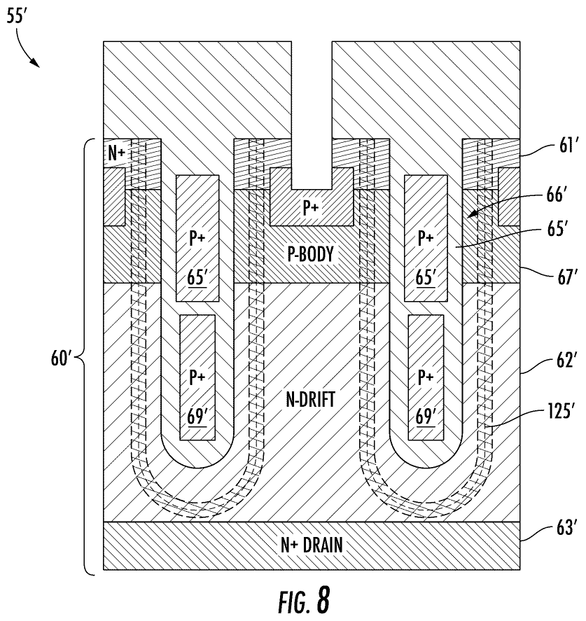

The in-situ doping of the superlattice layer 125, along with its dopant retention capabilities discussed further above, results in a dopant (e.g., phosphorous) pileup in the superlattice layer, as seen in the graph 70 of FIG. 5. This provides a significant technical advantage in terms of a sheet resistance reduction in the electron conduction path with respect to the drift layer 62 for Ron reduction. That is, the gettering properties of MST films discussed above advantageously allow the superlattice layer 125 to define the phosphorus pileup in the appropriate location to reduce Rₒₙ resistance. In an example 48V VDMOS implementation of the TFET 55, simulation results demonstrate that the in-situ doped superlattice layer 125 within the drift region 62 advantageously provides desired Rdson performance without significant breakdown voltage (BV) degradation, as seen in the series of graphs 75 of FIG. 6 comparing electrical performance between this implementation and a control TFET device having the same configuration but without the superlattice layer/in-situ dopant.

Another technical advantage of the in-situ doped superlattice layer 125 within the drift region 62 is that this allows more carrier conduction adjacent the shield gate electrode 68, resulting in increased current density due to the piled-up phosphorus. In addition, another significant technical advantage of the TFET 55 is that the dopant blocking characteristics of the superlattice layer 125 help block diffusion from the P+ body 68 into the channel 66, which results in improved threshold voltage (Vt) control and pitch reduction capability, as will also be appreciated by those skilled in the art.

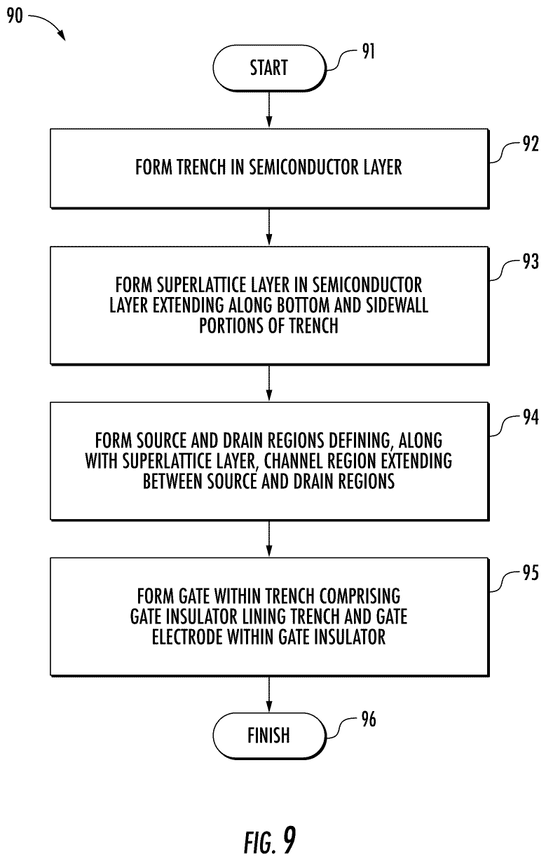

Turning to FIG. 8, another example implementation of the TFET 55′ is now described in which the gate electrode 64′ is oppositely doped (counter doped) with respect to the source and drain regions 61′, 63′ to provide a buried channel configuration. More particularly, the polysilicon gate is doped oppositely to the source/drain regions 61′, 63′ and the drift region 62′. This counter dopant is retained in place by the dopant constraining properties of the MST film, as discussed further above. The effect of this configuration is that the region where electrons flow is spaced apart from the interface with the gate 64′. Since buried channel provides a technical advantage of reduction of electric field and hence improvement of hot carrier injection (HCI) immunity at the same drain current compared to the conventional surface channel, in which the conductivity type of polysilicon gate electrode is the same as source/drain regions, it also contributes to further Ron and BV improvements, yet while still retaining on-state breakdown characteristics. It will be appreciated that the dopant types may be reversed in other configurations (e.g., a P channel device vs. an N channel).

Turning to the flow diagram 90 of FIG. 9, a related method for making the TFET 55 (or 55′) is now described. Beginning at Block 91, the method illustratively includes forming a trench in the semiconductor layer 60 (Block 92), and forming the superlattice layer 125 in the semiconductor layer extending along bottom and sidewall portions of the trench (Block 93). The method further illustratively includes forming source and drain regions 61, 63 defining, along with the superlattice layer, a channel region 66 extending between the source and drain regions (Block 94), and forming the gate 63 within the trench including the gate insulator 65 lining the trench and gate electrode 64 within the gate insulator (Block 95). Further semiconductor device processing may subsequently be performed, such as forming source/drain/gate contacts, etc., as will be appreciated by those skilled in the art. The method of FIG. 9 illustratively concludes at Block 96.

Many modifications and other embodiments will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included.

1. A method for making a trench field effect transistor (TFET) comprising:
forming a trench in a semiconductor layer;
forming a superlattice layer in the semiconductor layer extending along bottom and sidewall portions of the trench, the superlattice layer comprising a plurality of stacked groups of layers, each group of layers comprising a plurality of stacked base semiconductor monolayers defining a base semiconductor portion and at least one non-semiconductor monolayer, with each at least one non-semiconductor monolayer of each group of layers being constrained within a crystal lattice of adjacent base semiconductor portions;
forming source and drain regions defining, along with the superlattice layer, a channel region extending between the source and drain regions; and
forming a gate within the trench comprising a gate insulator lining the trench and a gate electrode within the gate insulator.

2. The method of claim 1 wherein the source and drain regions have a first conductivity type, and wherein the gate electrode has a second conductivity type different than the first conductivity type.

3. The method of claim 1 further comprising in-situ doping at least one base semiconductor portion of the superlattice layer between adjacent non-semiconductor monolayers.

4. The method of claim 3 wherein the in-situ dopant comprises phosphorous.

5. The method of claim 1 further comprising forming a shield gate electrode within the gate insulator beneath the gate electrode.

6. The method of claim 1 wherein the semiconductor layer has a first conductivity type adjacent a bottom of the trench defining a drift region, and a second conductivity type adjacent a top of the trench defining a body region.

7. The method of claim 1 wherein the gate insulator comprises an oxide.

8. The method of claim 1 wherein the gate electrode comprises a polysilicon gate electrode.

9. The method of claim 1 wherein the base semiconductor monolayers comprise silicon.

10. The method of claim 1 wherein the at least one non-semiconductor monolayer comprises oxygen.

11. A method for making a trench field effect transistor (TFET) comprising:
forming a trench in a semiconductor layer;
forming a superlattice layer in the semiconductor layer extending along bottom and sidewall portions of the trench, the superlattice layer comprising a plurality of stacked groups of layers, each group of layers comprising a plurality of stacked base semiconductor monolayers defining a base semiconductor portion and at least one non-semiconductor monolayer, with each at least one non-semiconductor monolayer of each group of layers being constrained within a crystal lattice of adjacent base semiconductor portions;
forming source and drain regions defining, along with the superlattice layer, a channel region extending between the source and drain regions; and
forming a gate within the trench comprising a gate insulator lining the trench and a gate electrode within the gate insulator, the gate electrode having a second conductivity type different than the first conductivity type;
wherein forming the superlattice layer comprises in-situ doping at least one base semiconductor portion between adjacent non-semiconductor monolayers.

12. The method of claim 11 wherein the in-situ dopant comprises phosphorous.

13. The method of claim 11 further comprising forming a shield gate electrode within the gate insulator beneath the gate electrode.

14. The method of claim 11 wherein the semiconductor layer has a first conductivity type adjacent a bottom of the trench defining a drift region, and a second conductivity type adjacent a top of the trench defining a body region.

15. A method for making a trench field effect transistor (TFET) comprising:
forming a trench in a semiconductor layer;
forming a superlattice layer in the semiconductor layer extending along bottom and sidewall portions of the trench, the superlattice layer comprising a plurality of stacked groups of layers, each group of layers comprising a plurality of stacked base silicon monolayers defining a base silicon portion and at least one oxygen monolayer, with each at least one non-semiconductor monolayer of each group of layers being constrained within a crystal lattice of adjacent base semiconductor portions;
forming source and drain regions defining, along with the superlattice layer, a channel region extending between the source and drain regions; and
forming a gate within the trench comprising a gate insulator lining the trench and a gate electrode within the gate insulator.

16. The method of claim 15 wherein the source and drain regions have a first conductivity type, and wherein the gate electrode has a second conductivity type different than the first conductivity type.

17. The method of claim 15 further comprising in-situ doping at least one base semiconductor portion of the superlattice layer between adjacent non-semiconductor monolayers.

18. The method of claim 17 wherein the in-situ dopant comprises phosphorous.

19. The method of claim 15 further comprising forming a shield gate electrode within the gate insulator beneath the gate electrode.

20. The method of claim 15 wherein the semiconductor layer has a first conductivity type adjacent a bottom of the trench defining a drift region, and a second conductivity type adjacent a top of the trench defining a body region.
